(19) United States
(12) Patent Application Publication
(10) Pub. No.: US 2023/0296986 A1
(43) Pub. Date: Sep. 21, 2023

(54) LITHOGRAPHIC APPARATUS AND METHODS FOR MULTI-EXPOSURE OF A SUBSTRATE

(71) Applicants: ASML Holding N.V., Veldhoven (NL); ASML Netherlands B.V., Veldhoven (NL)

(72) Inventors: Timothy Allan BRUNNER, Ridgefield, CT (US); Marcus Adrianus VAN DE KERKHOF, Helmond (NL)

(73) Assignees: ASML Holding N.V., Veldhoven (NL); ASML Netherlands B.V., Veldhoven (NL)

(21) Appl. No.: 18/017,365

(22) PCT Filed: Jul. 19, 2021
(86) PCT No.: PCT/EP2021/070189

§ 371 Date: Jan. 20, 2023

Related U.S. Application Data
(60) Provisional application No. 63/057,483, filed on Jul. 28, 2020.

(51) Int. Cl. G03F 7/20

(52) U.S. Cl. CPC G03F 7/70475; G03F 7/70466

(57) ABSTRACT

A lithographic system and a method for exposing a substrate are provided. The method includes providing a plurality of mask sets. Each mask set includes complementary masks corresponding to a respective pattern. The method further comprises exposing the substrate with the plurality of mask sets. A stitch location between the complementary masks of a mask set is different than a stitch location between the complementary masks of each other mask set of the plurality of mask sets.

### CROSS-REFERENCE TO RELATED APPLICATIONS

This application claims priority of U.S. Provisional Patent Application No. 63/057,483, which was filed on Jul. 28, 2020, and which is incorporated herein in its entirety by reference.

### FIELD

The present disclosure relates to lithographic systems and methods, for example, a method for applying a pattern on a substrate.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction.

Another lithographic system is an interferometric lithographic system where there is no patterning device, but rather a light beam is split into two beams, and the two beams are caused to interfere at a target portion of the substrate through the use of a reflection system. The interference causes lines to be formed at the target portion of the substrate.

During lithographic operation, different processing steps may require different layers to be sequentially formed on the substrate. Sequencing of layers is typically accomplished by exchanging different reticles, according to the desired pattern for each layer, for each pattern transfer process.

### SUMMARY

There is a need to provide improved exposure techniques to minimize errors at a stitching boundary.

In some embodiments, a method for exposing a substrate comprises providing a plurality of mask sets. Each mask set includes complementary masks corresponding to a respective pattern. The method further comprises exposing the substrate with the plurality of mask sets. A stitch location between the complementary masks of a mask set is different than a stitch location between the complementary masks of each other mask set of the plurality of mask sets.

In some embodiments, a multi-exposure patterning method comprises exposing a portion of a substrate using a first pair of masks, and re-exposing the same portion of the substrate using a second pair of masks. The second pair of masks has an identical pattern as the first pair of masks. A location of a stitch boundary between masks of the first pair of masks is different than the location of a stitch boundary between the masks of the second pair of masks.

In some embodiments, a lithographic apparatus comprises an illumination system and a projection system. The illumination apparatus is configured to illuminate a pattern of a plurality of patterning devices. The projections system is configured to project an image of each pattern of the plurality of patterning devices consecutively. A same portion of the substrate is exposed n times using at least two patterning devices. Each patterning device is associated with a half field and a full field being is created using at least two complementary patterning devices. The location of a stich boundary between the complementary patterning devices is different for each exposure.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some embodiments.

FIG. 1B shows a schematic of a transmissive lithographic apparatus, according to some embodiments.

FIG. 2 shows a more detailed schematic of the reflective lithographic apparatus, according to some embodiments.

FIG. 3 shows a schematic of a lithographic cell, according to some embodiments.

FIG. 4A shows a schematic that illustrates an exposure process flow according to some embodiments.

FIG. 4B shows a schematic that illustrates a vote-taking exposure process flow using a plurality of mask sets, according to some embodiments.

FIG. 5 shows a schematic that illustrates a stitch border between two masks, according to some embodiments.

FIG. 6 shows a schematic that illustrates critical dimension over a stitching zone, according to some embodiments.

FIG. 7 shows a schematic that illustrates an overlay error between two half-fields, according to some embodiments.

FIG. 8 shows a schematic of a pair of mask sets, according to some embodiments.

FIG. 9 is a flowchart for a method to expose a substrate, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc. The term “non-transitory” may be used herein to characterize computer readable media used for storing data, information, instructions, and the like, with the sole exception being a transitory, propagating signal.

Before describing such embodiments in more detail, however, it is instructive to present an example environment in which embodiments of the present disclosure can be implemented.

Example Lithographic Systems

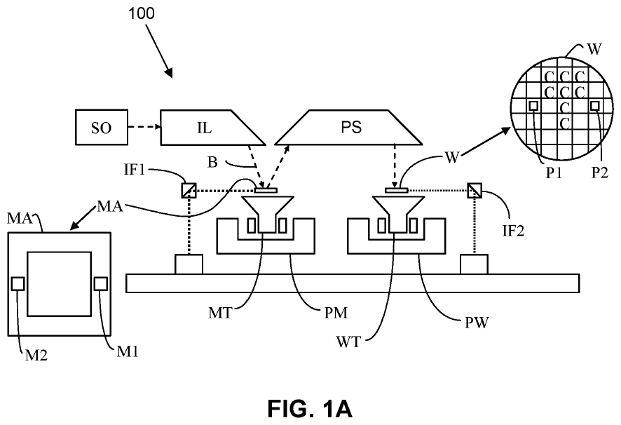

FIGS. 1A and 1B show schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT may be a frame or a table, for example, which may be fixed or movable, as required. By using sensors, the support structure MT may ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B may correspond to a particular functional layer in a device being created in the target portion C to form an integrated circuit.

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT may be used in parallel, or preparatory steps may be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ may be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO may be an integral part of the lithographic apparatus 100, 100′, for example, when the source SO is a mercury lamp. The source SO and the illuminator IL, together with the beam delivery system BD, if required, may be referred to as a radiation system.

The illuminator IL may include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator may be adjusted. In addition, the illuminator IL may comprise various other components (in FIG. 1B), such as an integrator IN and a condenser CO. The illuminator IL may be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT may be moved accurately (for example, so as to position different target portions C in the path of the radiation beam B). Similarly, the first positioner PM and another position sensor IF1 may be used to accurately position the patterning device (for example, mask) MA with respect to the path of the radiation beam B. Patterning device (for example, mask) MA and substrate W may be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image MP′ of the mask pattern MP, where image MP′ is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations).

With the aid of the second positioner PW and position sensor IF (for example, an interferometric device, linear encoder, or capacitive sensor), the substrate table WT may be moved accurately (for example, so as to position different target portions C in the path of the radiation beam B). Similarly, the first positioner PM and another position sensor (not shown in FIG. 1B) may be used to accurately position the mask MA with respect to the path of the radiation beam B (for example, after mechanical retrieval from a mask library or during a scan).

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the mask table MT may be connected to a short-stroke actuator only or may be fixed. Mask MA and substrate W may be aligned using mask alignment marks M1, M2, and substrate alignment marks P1, P2. Although the substrate alignment marks (as illustrated) occupy dedicated target portions, they may be located in spaces between target portions (known as scribe-lane alignment marks). Similarly, in situations in which more than one die is provided on the mask MA, the mask alignment marks may be located between the dies.

Mask table MT and patterning device MA may be in a vacuum chamber V, where an in-vacuum robot IVR may be used to move patterning devices such as a mask in and out of vacuum chamber. Alternatively, when mask table MT and patterning device MA are outside of the vacuum chamber, an out-of-vacuum robot may be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ may be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT may be determined by the (de-)magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes a programmable patterning device, such as a programmable mirror array.

Combinations and/or variations on the described modes of use or entirely different modes of use may also be employed.

In some embodiments, a lithographic apparatus may generate DUV and/or EUV radiation. For example, lithographic apparatus 100′ may be configured to operate using a DUV source. In another example, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

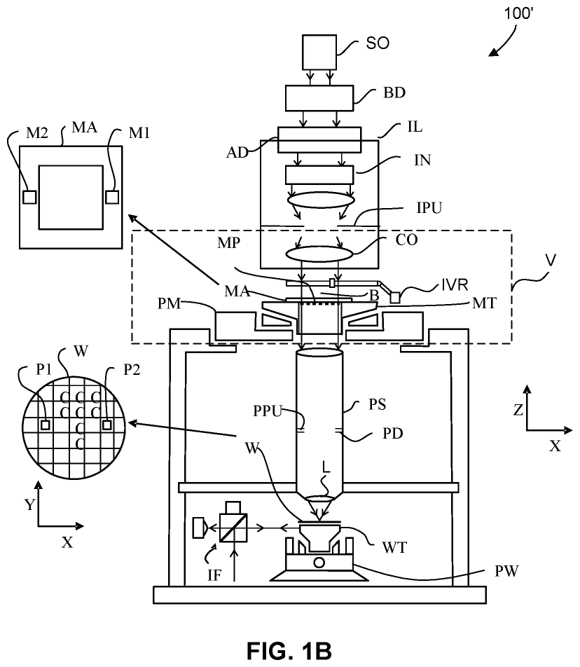

FIG. 2 shows the lithographic apparatus 100 in more detail, including the source collector apparatus SO, the illumination system IL, and the projection system PS. The source collector apparatus SO is constructed and arranged such that a vacuum environment may be maintained in an enclosing structure 220 of the source collector apparatus SO. An EUV radiation emitting plasma 210 may be formed by a discharge produced plasma source. EUV radiation may be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure.

The collector chamber 212 may include a radiation collector CO, which may be a so-called grazing incidence collector. Radiation collector CO has an upstream radiation collector side 251 and a downstream radiation collector side 252. Radiation that traverses collector CO may be reflected off a grating spectral filter 240 to be focused in a virtual source point IF. The virtual source point IF is commonly referred to as the intermediate focus, and the source collector apparatus is arranged such that the intermediate focus IF is located at or near an opening 219 in the enclosing structure 220. The virtual source point IF is an image of the radiation emitting plasma 210. Grating spectral filter 240 is used in particular for suppressing infra-red (IR) radiation.

Subsequently the radiation traverses the illumination system IL, which may include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination optics unit IL and projection system PS. The grating spectral filter 240 may optionally be present, depending upon the type of lithographic apparatus. Further, there may be more mirrors present than those shown in the FIG. 2, for example there may be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

Exemplary Lithographic Cell

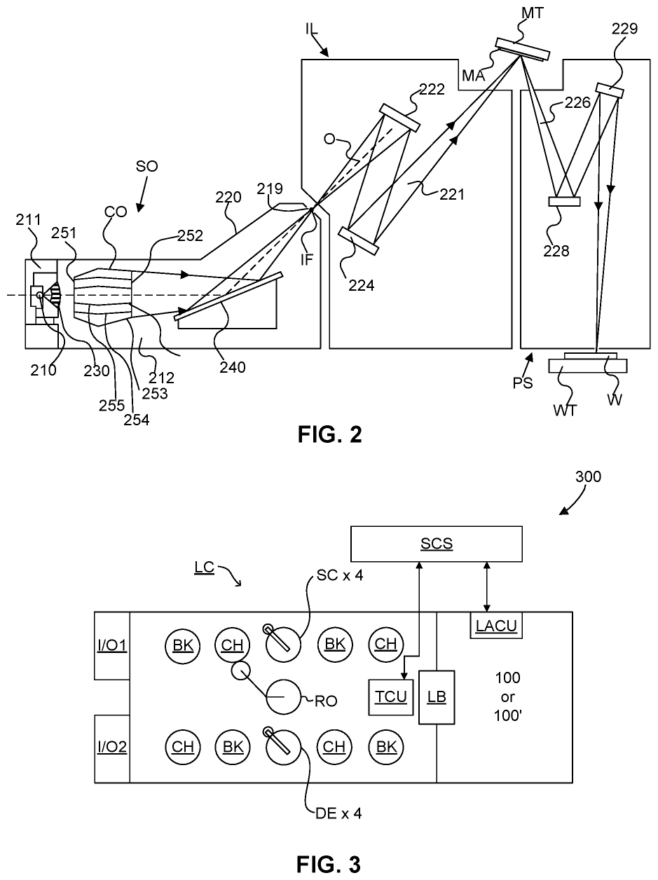

FIG. 3 shows a lithographic cell 300, also sometimes referred to a lithocell or cluster, according to some embodiments. Lithographic apparatus 100 or 100′ may form part of lithographic cell 300. Lithographic cell 300 may also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses may be operated to maximize throughput and processing efficiency.

Vote-Taking Lithographic System

In one embodiment, a lithographic apparatus can pattern a half-field or a half reticle field. Yet, a full-field may need to be patterned using the lithographic apparatus. A full-field is about 26 mm×33 mm, for example. A half-field is about 26 mm×16.5 mm, for example. A full-field pattern may be built out of two half-fields. For example, two half-fields are “stitched” together to form a full-field. In one embodiment, a field may be built out of one or more half-fields and/or one or more full-fields to extend the chip size to above the maximum scanner field of 26 mm×33 mm such as in large-frame image sensor chips or in high-end server chips. A boundary between the two half-fields is referred to as a stitch boundary. There is a large concern that pattern quality is compromised at the stitch boundary due to small stage errors, lens distortions, and image flare resulting in overlay and CD errors near the stitch as described further below.

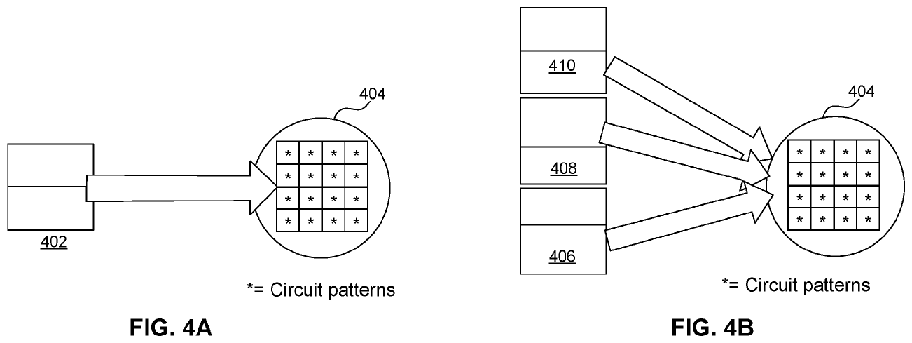

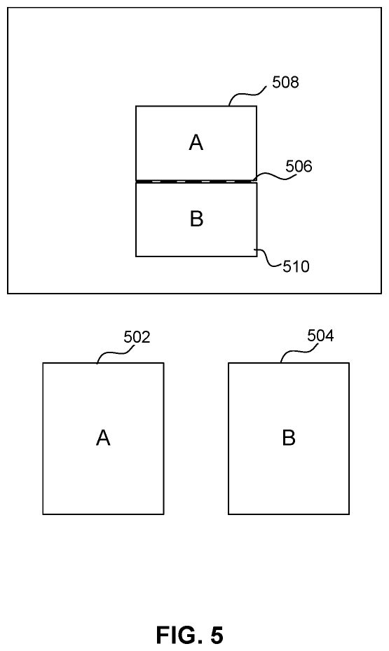

FIG. 4A illustrates a conventional exposure process flow to obtain a full-field from two half-fields according to one example. In order to expose a full-field, a mask set 402 is used. The mask set is associated with a desired circuit pattern. Each mask (reticle) of the mask set is exposed sequentially across a substrate 404. The mask set 402 may include a pair of masks as illustrated in FIG. 5. The mask set 402 can include a first mask 502 and a second mask 504. In one example, first mask 502 can be exposed across substrate 404. Then, second mask 504 can be exposed across substrate 404. In one embodiment, first mask 502 can be exposed across all substrates in a lot. Then, the reticle is changed from the first to the second mask 504. Then, the second mask 504 is exposed across all substrates of the lot.

A stitch boundary 506 between a first half field 508 and a second half field 510 on a substrate is shown in FIG. 5. First mask 502 and second mask 504 are used to expose a first half field (top field) 508 and a second half field (bottom field) 510, respectively. The area in the vicinity of the stitch boundary 506 is known to have problems with CD and overlay errors.

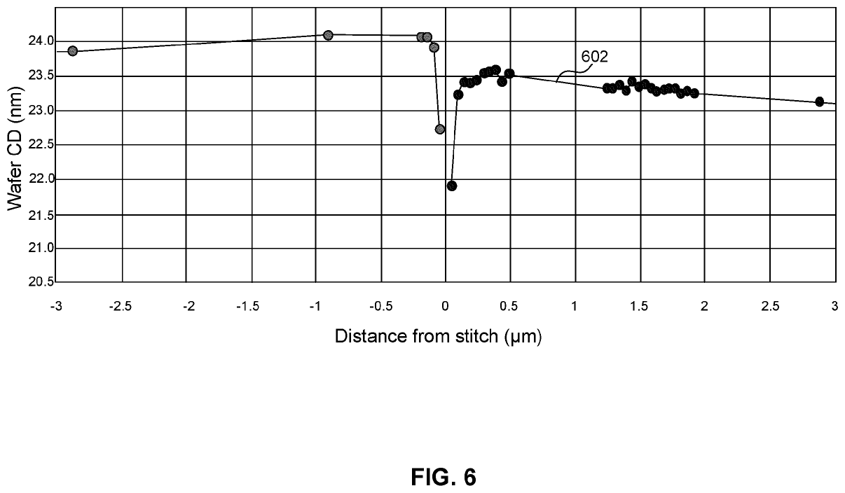

CD errors near the stitch boundary may have multiple causes such as image flare from neighboring chip or “black border.” Further, an upper half-field could be vertically shifted relative to the lower half-field which can lead to an under-exposed “gap” and/or could lead to a double-exposed area. Wafer CD across a slit is shown in FIG. 6. Trace 602 shows a 2 nm CD deviation across the stitch boundary.

Overlay errors may also have multiple causes. For example, overlay errors may be due to a local relative rotation between two half-fields, a relative X or Y translation shift between the two half-fields, and/or a relative magnification shift between two half-fields. Overlay errors may also be due to lens distortion being different between the top of field and the bottom of field.

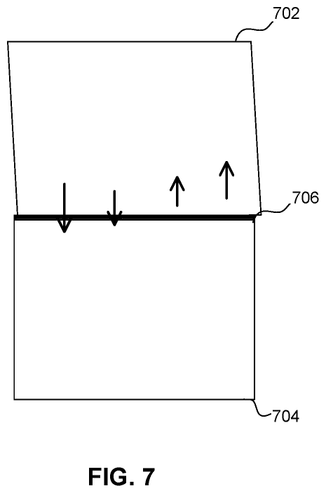

FIG. 7 is a schematic that illustrates an overlay error at the stitch boundary caused by a rotation between the two half-fields. For example, a first mask 702 may be rotated with respect to a second mask 704 causing overlay errors at the stich boundary 706. The arrows in FIG. 7 illustrate a rotation of the first mask 702 with respect to the second mask 704.

In one embodiment, a multi-exposure process is used to reduce errors at the stitch location. A plurality of mask sets may be used to expose the pattern on a substrate using multiple passes or exposures. The pattern may be divided into two or more subfield patterns. Each mask set includes complementary masks. In other words, each mask of the mask set is associated with a subfield pattern of the pattern such that exposing the complementary masks will form the complete pattern. The plurality of mask sets have substantially an identical (i.e., the same) pattern. A boundary location between the two or more subfields of each mask set is different than a boundary location of each other mask set of the plurality of mask sets. Thus, each mask set is designed such that when exposed the stitch boundary would be at a different location on the substrate. Each mask set is exposed using an exposure dose that is less than a nominal exposure dose.

FIG. 4B illustrates a vote-taking exposure process flow using a plurality of mask sets according to one example. Three mask sets (N=3) 406, 408, 410 are shown in FIG. 4B. The mask sets 406, 408, 410 have nominally identical patterns. The mask sets 406, 408, 410 are exposed in sequence at the same location on the substrate 404, each with an equal fraction of the nominal exposure dose. For example, each mask set may be exposed with one-third (⅓) of the nominal exposure dose. Each mask set includes at least two masks each being associated with a half field (e.g., top field and bottom field). The location of a boundary in each mask set of the mask sets 406, 408, 410 is different from the location of a mask set used in the multi-exposure process. Consequently, in a scheme using N mask sets, error at the stitching from one set affects only 1/N of the total exposure. The pattern may include N partial stitches (for an N-pass voting). In this manner stitching errors can be reduced by a factor of N. Thus, for N=3, the pattern may include 3 stitch locations each having less errors compared to a single stitch location.

In one embodiment, a two-pass process is implemented using two mask sets. Each mask set includes a pair of masks. In a first pass, a portion of a substrate is exposed using the first mask set. In a second pass, the same portion of the substrate is re-exposed.

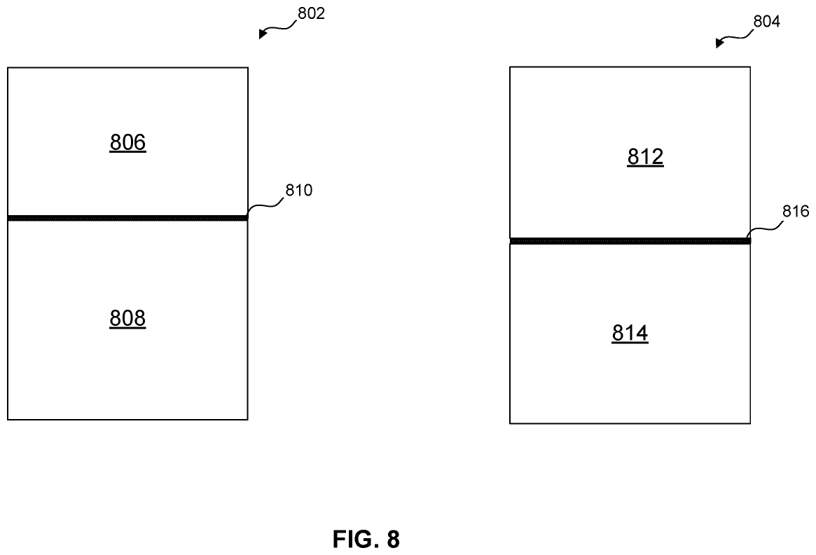

FIG. 8 illustrates a first mask pair 802 and a second mask pair 804 for N=2 vote-taking process, according to one example. First mask pair 802 can include a first mask 806 and a second mask 808. Second mask pair 804 can include a third mask 812 and a fourth mask 814. The stitch of a first mask pair 802 is designed in a different location than for a second mask pair 804. In other words, a boundary 810 between first mask 806 and second mask 808 is at different location than a boundary 816 between third mask 812 and fourth mask 814. In one example, each mask of first mask 806 and second mask 808 can correspond to half of the pattern with a location of the boundary 810 corresponding to the middle of the pattern (i.e., horizontal middle). A location of boundary 816 can be designed to be lower than the location of boundary 810 in this example. Alternatively, the location of boundary 816 can be designed to be higher than the location of boundary 810.

First mask 806 of the first mask pair 802 is exposed across the substrate at dose fraction one half (½) of a nominal exposure dose. The first mask 806 is exchanged with the second mask 808. The second mask 808 is exposed across the substrate. The second mask 808 is exchanged with the third mask 812 and the third mask 812 is exposed across the substrate. Then, the third mask 812 is exchanged with the fourth mask 814 and the substrate is re-exposed at dose fraction ½ of the nominal exposure dose.

In some embodiments, a lot may include a plurality of substrates. Each mask of the masks is exposed across the plurality of the substrates in the lot before being exchanged. For example, the first mask 806 is exposed across the plurality of the substrates in the lot. Once all the substrates has been exposed, the first mask 806 is exchanged with the second mask 808 and the second mask 808 is exposed across the plurality of substrates.

In some embodiments, after exposing with the last reticle (mask), the lot proceeds to post-exposure bake (PEB) and development as would be understood by one of ordinary skill in the art. The pattern will show two stitch locations (for N=2). The two half-stitches are expected to have stitch-related CD and overlay errors reduced by a factor of two compared with a full stitch. For example, the 2 nm deviation shown in FIG. 6 may be reduced to approximately 1 nm. Other CD deviation or overlay deviation errors across the stitch boundary are also reduced by a factor of 2.

In some embodiments, the reticle is changed after exposing each substrate of the plurality of the substrates in the lot. For example, the first mask 806 can be exposed across a first substrate of the plurality of the substrates. Then, the first mask 806 is exchanged with the second mask 808. Then, the second mask 808 can be exposed across the first substrate. The second mask 808 can be exchanged with the third mask 812 and the third mask 812 can be exposed across the substrate. Then, the third mask 814 is exchanged with the fourth mask 816. Once, the exposure of the first substrate is done, then another substrate of the plurality of substrates of the lot may be exposed.

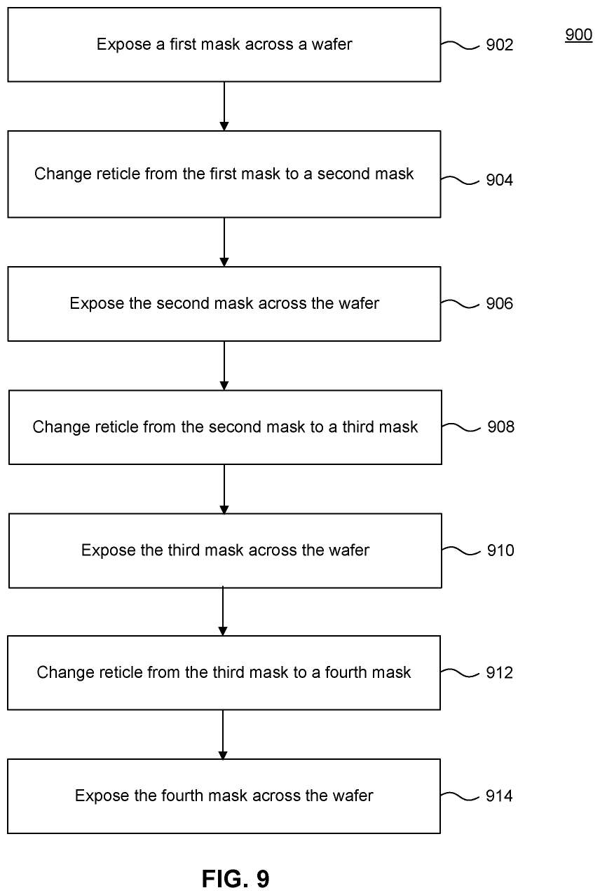

FIG. 9 shows a method 900 for exposing substrate according to one example. It should be understood that the operations shown in method 900 are not exhaustive and that other operations can be performed as well before, after, or between any of the illustrated operations. In various embodiments of the present disclosure, the operations of method 900 can be performed in a different order and/or with different devices than those described as exemplary.

At step 902, a first mask set is provided. The first mask set may include a pair of masks. For example, the first mask set may include a first mask and a second mask. The first mask is exposed across one or more substrates included in a lot to pattern a first field. The lot may include twenty substrates.

At step 904, the first mask is exchanged with the second mask.

At step 906, the second mask of the first mask set is exposed across the one or more substrates to pattern a second half field.

At step 908, a second mask set is provided. The second mask may include another pair of masks having the same pattern as the first mask set. As discussed previously herein, the boundary between the first half field and the second half field is different than the first mask set. For example, the second mask set may include a third mask and a fourth mask. The second mask is exchanged with the third mask.

At step 910, the third mask is exposed across the one or more substrates. The third mask is exposed over the same full field formed by the first half field and the second field. In other words, the third mask is exposed over a portion of an image formed by the first mask set on the substrate.

At step 912, the third mask is exchanged with the fourth mask.

At step 914, the fourth mask is exposed across the one or more substrates. The fourth mask is exposed over another portion of the image formed by the first mask set. Thus, the image pattern formed by the second mask set is formed over the image pattern formed using the first mask set. Thus, the formed image pattern include two distinct stitching boundaries.

While the throughput burden of using four or more masks and vote-taking to expose a full field are considerable, additional benefits can be obtained. Lens heating, reticle heating, and wafer heating are mitigated by breaking up the exposure into two passes with half the exposure dose. The vote-taking lithography process also reduces the sensitivity to mask defects. In some embodiments, lithographic systems that enables stitching together two half-fields, also enables voting methods. The lithography system described herein may support full throughput voting lithography, e.g. using rapid reticle exchange.

The embodiments may further be described using the following clauses:
1. A method for exposing a substrate, the method comprising:
   providing a plurality of mask sets, each mask set including complementary masks corresponding to a respective pattern; and
   exposing the substrate with the plurality of mask sets, wherein
   a stitch location between the complementary masks of a mask set is different than a stitch location between the complementary masks of each other mask set of the plurality of mask sets.
2. The method of clause 1, wherein each mask set includes a pair of masks.
3. The method of clause 2, wherein the plurality of mask sets includes a first mask set and a second mask set.
4. The method of clause 3, wherein the respective pattern of the first mask set and the respective pattern of the second mask set are identical.
5. The method of clause 3, wherein exposing the substrate includes:
   exposing the substrate using a first mask of the first mask set;
   exposing the substrate using a second mask of the first mask set;
   exposing the substrate using a third mask of the second mask set; and
   exposing the substrate using a fourth mask of the second mask set, wherein a region of the substrate that has been exposed by the first mask set is exposed by the second mask set.
6. The method of clause 5, further comprising exposing a plurality of substrates using each mask of the first mask, the second mask, the third mask, and the fourth mask consecutively.
7. The method of clause 2, wherein exposing the substrate includes exposing a half field by each mask.
8. The method of clause 1, wherein each mask is exposed with an exposure dose less than a nominal exposure dose.
9. The method of clause 8, wherein each mask is exposed with equal fractions of the nominal exposure dose.
10. A multi-exposure patterning method, the method comprising:
   exposing a portion of a substrate using a first pair of masks; and
   re-exposing the same portion of the substrate using a second pair of masks, the second pair of masks having an identical pattern as the first pair of masks, wherein a location of a stitch boundary between masks of the first pair of masks is different than the location of a stitch boundary between the masks of the second pair of masks.
11. The method of clause 10, wherein exposing a portion of a substrate includes:
   exposing the substrate with a first mask of the first pair of masks; and
   exposing the substrate with a second mask of the first pair of masks, each of the first mask and the second mask being associated with a half-field of an image field.
12. The method of clause 11, further comprising:
   exposing at least another substrate with the first mark before exposing the substrate with the second mask.
13. The method of clause 10, wherein each mask is exposed with an exposure dose equals to half of a nominal exposure dose.
14. The method of clause 10, wherein a pattern on the substrate includes at least two stitch locations.
15. A lithographic system comprising:
   an illumination apparatus configured to illuminate a pattern of a plurality of patterning devices; and
   a projection system configured to project an image of each pattern of the plurality of patterning devices consecutively, wherein
   a same portion of the substrate is exposed n times using at least two patterning devices, each patterning device being associated with a half field, a full field being created using at least two sets of complementary patterning devices, and
   a location of a stich boundary between the complementary patterning devices is different for each exposure.
16. The lithographic system of clause 15, wherein each pattern of the plurality of patterning devices is exposed by one nth of a nominal exposing dose.
17. The lithographic system of clause 15, wherein the same portion is exposed twice.
18. The lithographic system of clause 17, wherein the substrate is exposed by one-half of a nominal exposing dosing using two sets of complementary patterning devices.
19. The lithographic system of clause 15, wherein an image of the pattern on the substrate includes at least two distinct stitch location.
20. The lithographic system of clause 15, wherein the at least two sets of complementary patterning devices have identical pattern.

In some embodiments, metrology systems described herein may be implemented in a larger system, for example, within a lithographic apparatus.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as synonymous with the more general terms “substrate” or “target portion”, respectively. The substrate referred to herein can be processed, before or after exposure, in for example a track unit (a tool that typically applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure can be used in other applications, for example in electron-beam and ion-beam system.

It is to be understood that the phraseology or terminology herein is for the purpose of description and not of limitation, such that the terminology or phraseology of the present disclosure is to be interpreted by those skilled in relevant art(s) in light of the teachings herein.

The term “substrate” as used herein describes a material onto which material layers are added. In some embodiments, the substrate itself can be patterned and materials added on top of it may also be patterned, or may remain without patterning.

Although specific reference can be made in this text to the use of the apparatus and/or system according to the present disclosure in the manufacture of ICs, it should be explicitly understood that such an apparatus and/or system has many other possible applications. For example, it can be employed in the manufacture of integrated optical systems, guidance and detection patterns for magnetic domain memories, LCD panels, thin-film magnetic heads, etc. The skilled artisan will appreciate that, in the context of such alternative applications, any use of the terms “reticle,” “wafer,” or “die” in this text should be considered as being replaced by the more general terms “mask,” “substrate,” and “target portion,” respectively.

While specific embodiments of the present disclosure have been described above, it will be appreciated that the present disclosure can be practiced otherwise than as described. The description is not intended to limit the present disclosure.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of protected subject matter should not be limited by any of the above-described exemplary embodiments, but should be defined only in accordance with the following claims and their equivalents.

1. A method for exposing a substrate, the method comprising:
providing a plurality of mask sets, each mask set including complementary masks corresponding to a respective pattern; and
exposing the substrate with the plurality of mask sets, wherein
a stitch location between the complementary masks of a mask set is different than a stitch location between the complementary masks of each other mask set of the plurality of mask sets.

2. The method of claim 1, wherein each mask set includes a pair of masks.

3. The method of claim 2, wherein the plurality of mask sets includes a first mask set and a second mask set.

4. The method of claim 3, wherein the respective pattern of the first mask set and the respective pattern of the second mask set are identical.

5. The method of claim 3, wherein exposing the substrate includes:
exposing the substrate using a first mask of the first mask set;
exposing the substrate using a second mask of the first mask set;
exposing the substrate using a third mask of the second mask set; and
exposing the substrate using a fourth mask of the second mask set, wherein a region of the substrate that has been exposed by the first mask set is exposed by the second mask set.

6. The method of claim 5, further comprising exposing a plurality of substrates using each mask of the first mask, the second mask, the third mask, and the fourth mask consecutively.

7. The method of claim 2, wherein exposing the substrate includes exposing a half field by each mask.

8. The method of claim 1, wherein each mask is exposed with an exposure dose less than a nominal exposure dose.

9. The method of claim 8, wherein each mask is exposed with equal fractions of the nominal exposure dose.

10. A multi-exposure patterning method, the method comprising:
exposing a portion of a substrate using a first pair of masks; and
re-exposing the same portion of the substrate using a second pair of masks, the second pair of masks having an identical pattern as the first pair of masks, wherein a location of a stitch boundary between masks of the first pair of masks is different than the location of a stitch boundary between the masks of the second pair of masks.

11. The method of claim 10, wherein exposing a portion of a substrate includes:
exposing the substrate with a first mask of the first pair of masks; and
exposing the substrate with a second mask of the first pair of masks, each of the first mask and the second mask being associated with a half-field of an image field.

12. The method of claim 11, further comprising:
exposing at least another substrate with the first mark before exposing the substrate with the second mask.

13. The method of claim 10, wherein each mask is exposed with an exposure dose equals to half of a nominal exposure dose.

14. The method of claim 10, wherein a pattern on the substrate includes at least two stitch locations.

15. A lithographic system comprising:
an illumination apparatus configured to illuminate a pattern of a plurality of patterning devices; and
a projection system configured to project an image of each pattern of the plurality of patterning devices consecutively, wherein
a same portion of the substrate is exposed n times using at least two patterning devices, each patterning device being associated with a half field, a full field being created using at least two sets of complementary patterning devices, and
a location of a stich boundary between the complementary patterning devices is different for each exposure.
